(19) United States
(12) Patent Application Publication
(10) Pub. No.: US 2018/0197761 A1
(43) Pub. Date: Jul. 12, 2018

(54) ACTIVE WORKPIECE HEATING OR COOLING FOR AN ION IMPLANTATION SYSTEM

(71) Applicant: Axcelis Technologies, Inc., Beverly, MA (US)

(72) Inventors: Joseph Ferrara, Georgetown, MA (US); Brian Terry, Amesbury, MA (US); John Baggett, Amesbury, MA (US)

(21) Appl. No.: 15/866,209

(22) Filed: Jan. 9, 2018

Related U.S. Application Data
(60) Provisional application No. 62/444,620, filed on Jan. 10, 2017.

(51) Int. Cl. H01L 21/67; C23C 14/48; H01L 21/683; H01L 21/687; C23C 14/56; H01J 37/317

(52) U.S. Cl. CPC H01L 21/67248; C23C 14/48; H01L 21/6833; H01J 37/3171; H01L 21/68728; C23C 14/56; H01L 21/67098

(57) ABSTRACT

A heated chuck for an ion implantation system selectively clamps a workpiece to a carrier plate having heaters to selectively heat a clamping surface. A gap between a base plate and carrier plate of the heated chuck contains a heat transfer media. A cooling fluid source is coupled to cooling channels in the base plate. A controller operates the heated chuck in a first mode and second mode. In the first mode, the controller does not activate the heaters and flows the cooling fluid through the cooling channel, where heat is transferred through the heat transfer media and to the cooling fluid. In the second mode, the controller activates the heaters and optionally purges the cooling fluid from the cooling channel or otherwise alters its cooling capacity. A gas can be selectively provided in the gap to further control heat transfer in the first and second modes.

### REFERENCE TO RELATED APPLICATIONS

This application claims the benefit of U.S. Provisional Application No. 62/444,620 filed Jan. 10, 2017, entitled “ACTIVE WORKPIECE HEATING OR COOLING FOR AN ION IMPLANTATION SYSTEM”, the contents of which are herein incorporated by reference in their entirety.

### FIELD

The present disclosure relates generally to workpiece processing systems and methods for processing workpieces, and more specifically to a system and method for controlling a temperature of a workpiece in multiple modes utilizing the same electrostatic chuck in an ion implantation system.

### BACKGROUND

In semiconductor processing, many operations, such as ion implantation, may be performed on a workpiece or semiconductor wafer. As ion implantation processing technology advances, a variety of ion implantation temperatures at the workpiece can be implemented to achieve various implantation characteristics in the workpiece. For example, in conventional ion implantation processing, three temperature regimes are typically considered: cold implants, where process temperatures at the workpiece are maintained at temperatures below room temperature, hot implants, where process temperatures at the workpiece are maintained at high temperatures typically ranging from 100-600° C., and so-called quasi-room temperature implants, where process temperatures at the workpiece are maintained at temperatures slightly elevated above room temperature, but lower than those used in high temperature implants, with quasi-room temperature implant temperatures typically ranging from 50-100° C.

Hot implants, for example, are becoming more common, whereby the process temperature is typically achieved via a dedicated high temperature electrostatic chuck (ESC), also called a heated chuck. The heated chuck holds or clamps the workpiece to a surface thereof during implantation. A conventional high temperature ESC, for example, comprises a set of heaters embedded under the clamping surface for heating the ESC and workpiece to the process temperature (e.g., 100° C.-600° C.), whereby a gas interface conventionally provides a thermal interface from the clamping surface to the backside of the workpiece. Typically, a high temperature ESC is cooled through radiation of energy to the chamber surfaces in the background.

Chilled ion implantation processes are also common, where conventionally, a room temperature workpiece is placed on a chilled chuck, and the chilled chuck is cooled to a chilled temperature (e.g., a temperature below room temperature), thereby cooling the workpiece. Cooling the chilled chuck provides for a removal of thermal energy imparted into the workpiece from the ion implantation, while further maintaining the chuck and workpiece at the chilled temperature during the implant via the removal of heat through the chilled chuck.

Ion implantation processes are also performed at so-called “quasi-room temperature” (e.g., a temperature slightly elevated above room temperature, such as at 50-60° C., but not as high as a hot ion implantation process), whereby a low-heat chuck (e.g., a chuck configured to heat to a temperature less than 100° C.) has been conventionally used to control the temperature of the workpiece during implantation.

Typically, high temperature ESCs (e.g., heated chucks) are only utilized for hot implants, as they pose a problem if the desired processing is changed from high temperature processing (e.g., 100° C.-600° C.) to a quasi-room temperature processing (e.g., <100° C.) due, at least in part, to the configuration of the heaters therein, and control mechanisms for controlling the temperature of the implant. Thus, when changing from a high temperature implant to a quasi-room temperature implant, the heated chuck would be replaced by a low-heat chuck, whereby the heated chuck and low-heat chuck have differing heat transfer capabilities specifically designed for the desired processing temperature.

### SUMMARY OF THE INVENTION

The present invention overcomes the limitations of the prior art by providing a system and method for implanting workpieces on a single heated electrostatic chuck, whereby the system and method provide a configuration for both high temperature and quasi-room temperature implants without physically modifying the heated electrostatic chuck.

Accordingly, the following presents a simplified summary of the invention in order to provide a basic understanding of some aspects of the invention. This summary is not an extensive overview of the invention. It is intended to neither identify key or critical elements of the invention nor delineate the scope of the invention. Its purpose is to present some concepts of the invention in a simplified form as a prelude to the more detailed description that is presented later.

The present invention is directed generally toward an ion implantation system configured to implant ions into a workpiece. A heated chuck, for example, is positioned within a process chamber, wherein the heated chuck is configured to selectively clamp a workpiece to a clamping surface thereof. The heated chuck, for example, comprises a carrier plate having a clamping surface for clamping the workpiece thereto. The carrier plate has one or more heaters embedded therein or otherwise associated therewith, wherein the one or more heaters are configured to selectively heat the clamping surface. A base plate is operably coupled to the carrier plate, wherein a gap is provided between the base plate and carrier plate. One or more cooling channels are further defined in the base plate. A heat transfer media is further selectively disposed in the gap. According to one example, a source of a cooling fluid is further selectively operably coupled to the cooling channel.

A controller, for example, is configured to selectively operate the ion implantation system in one of a first mode and second mode. In the first mode, the controller is configured to not activate the one or more heaters and to flow the cooling fluid through the cooling channel. Accordingly, heat is transferred through the heat transfer media between the carrier plate and base plate, therein transferring heat to the cooling fluid. In the second mode, the controller is configured to activate the one or more heaters to a predetermined temperature and to optionally purge the cooling fluid from the cooling channel.

According to one example, a gas and vacuum source is further provided, wherein the heat transfer media comprises a gas. The controller, for example, is further configured to selectively supply the gas to the gap at a predetermined pressure in the first mode via a control of the gas and vacuum source. As such, the carrier plate is selectively thermally coupled to the base plate. The controller, for example, is further configured to selectively evacuate the gap via a control of the gas and vacuum source in the second mode, therein selectively thermally isolating the carrier plate from the base plate. In one or more examples, the predetermined pressure is approximately 5 Torr, and the gap is approximately 10 microns.

In accordance with another example, the heat transfer media comprises one or more of a gel, a flexible material, and a paste configured to transfer heat between the carrier plate and base plate. In another example, the heated chuck, is configured to heat the workpiece to a predetermined processing temperature, such as processing temperature ranges from approximately 100 C to approximately 200 C. In yet another example, the system comprises one or more of a pre-heat station and a post-cooling station for pre-heating or post-cooling the workpiece before or after being placed on the chuck.

In accordance with another exemplary aspect of the disclosure, a heated chuck is provided comprising a carrier plate and a base plate having a cooling channel defined therein. The base plate is operably coupled to the carrier plate, wherein a gap is defined between the carrier plate and the base plate, and wherein a heat transfer media is selectively provided in the gap. One or more are further provided, wherein the heated chuck is selectively operable in a first mode and second mode. In the first mode, the one or more heaters are not active and the cooling fluid is flowed through the cooling channel in the base plate, wherein heat is transferred through the heat transfer media between the carrier plate and base plate. In the second mode, the one or more heaters are activated to a predetermined temperature, and the cooling fluid can be optionally purged from the cooling channel.

In one example, a source of a cooling fluid selectively operably coupled to the cooling channel, and a controller is configured to selectively control an operation of the heated chuck in the first mode and second mode via a control of the one or more heaters, the source of the cooling fluid, and the heat transfer media.

In accordance with still another exemplary aspect of the disclosure, a method for implanting ions into a workpiece in a plurality of modes is provided. The method comprises selectively operating a heated chuck of an ion implantation system in one of a first mode and second mode. The method, for example, comprises electrostatically clamping the workpiece to a clamping surface of the heated chuck. In the first mode, the controller deactivates one or more heaters in a heated chuck and flows a cooling fluid through a cooling channel in the heated chuck. In the first mode, heat is transferred through a heat transfer media disposed in a gap between a carrier plate and a base plate of the chuck, therein transferring heat to the cooling fluid. In the second mode, the one or more heaters are activated to a predetermined temperature, and the cooling fluid may be purged from the cooling channel.

In one example, the heat transfer media comprises a gas, wherein in the first mode, the gas is supplied to the gap at a predetermined pressure, therein thermally coupling the carrier plate to the base plate. In the second mode, the gap is evacuated, therein generally thermally isolating the carrier plate from the base plate. For example, the heated chuck heats the workpiece to a predetermined processing temperature, where the processing temperature is approximately room temperature in the first mode and ranges from approximately 100 C to approximately 200 C in the second mode.

In yet another example, the method further comprises performing an ion implantation into the workpiece. One or more of pre-heating the workpiece before the implantation and post-cooling the workpiece after the implantation may be further performed.

To the accomplishment of the foregoing and related ends, the invention comprises the features hereinafter fully described and particularly pointed out in the claims. The following description and the annexed drawings set forth in detail certain illustrative embodiments of the invention. These embodiments are indicative, however, of a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

FIG. 1 illustrates a block diagram of an exemplary heated ion implantation system in accordance with an aspect of the present disclosure.

FIG. 2 is a perspective view of a top of a clamping surface of an ESC in accordance with an aspect of the present disclosure.

FIG. 3 is a perspective view of a bottom of an ESC in accordance with an aspect of the present disclosure.

FIG. 4A is a partial cross-sectional perspective view of an ESC in accordance with an aspect of the present disclosure.

FIG. 4B is a partial side view of an ESC in accordance with an aspect of the present disclosure.

FIG. 5 is a block diagram illustrating an exemplary method for room temperature ion implantation of workpieces according to another exemplary aspect of the disclosure.

FIG. 6 is a block diagram illustrating an exemplary method for heated ion implantation of workpieces according to another exemplary aspect of the disclosure.

FIG. 7 is a block diagram illustrating an exemplary control system in accordance with another aspect.

### DETAILED DESCRIPTION

The present invention is directed generally toward ion implantation systems, and more particularly, to an ion implantation system and chuck configured for both hot and quasi-room temperature implants. Accordingly, the present invention will now be described with reference to the drawings, wherein like reference numerals may be used to refer to like elements throughout. It should be understood that the description of these aspects are merely illustrative and that they should not be interpreted in a limiting sense. In the following description, for purposes of explanation, numerous specific details are set forth in order to provide a thorough understanding of the present invention. It will be evident to one skilled in the art, however, that the present invention may be practiced without these specific details.

Heated ion implantation processes can heat a workpiece to process temperatures in the range of 100 C-200 C. The process temperature, for example, is, in part, achieved and maintained at an electrostatic chuck that supports the workpiece during implantation. In order to reduce cost of ownership, the present disclosure provides an ion implanter that is capable of not only performing heated implants, but also implants with a workpiece starting at ambient (room) temperature that maintains temperatures below approximately 100 C. In order to achieve this, active cooling of the workpiece is also provided for this mode of operation. The present disclosure provides a system that can quickly change modes of operation between heating and cooling of the workpiece, with no physical changes to hardware.

Further, a system that has workpiece heating followed by workpiece processing on an electrostatic chuck (ESC) will have a significant impact to workpiece throughput and lower cost of ownership. Axcelis Technologies of Beverly, Mass. has designed a preheat station which elevates workpiece temperature to the implant temperature (e.g., in the range of approximately 100 C to approximately 200 C), before the workpiece is transferred and handed off to the ESC, whereby the ESC is maintained at the desired implant temperature, based on the desired implantation process. The preheat station adds a benefit of parallel heating of the workpiece, which directly impacts throughput, since subsequent workpieces can be heated (e.g., pre-heated) while the first workpiece is being processed (e.g., implanted) on the ESC. Further, preheating of the workpiece to temperatures relatively close in range to those used during processing will significantly mitigate the risks of generating particles and workpiece damage due to thermal expansion.

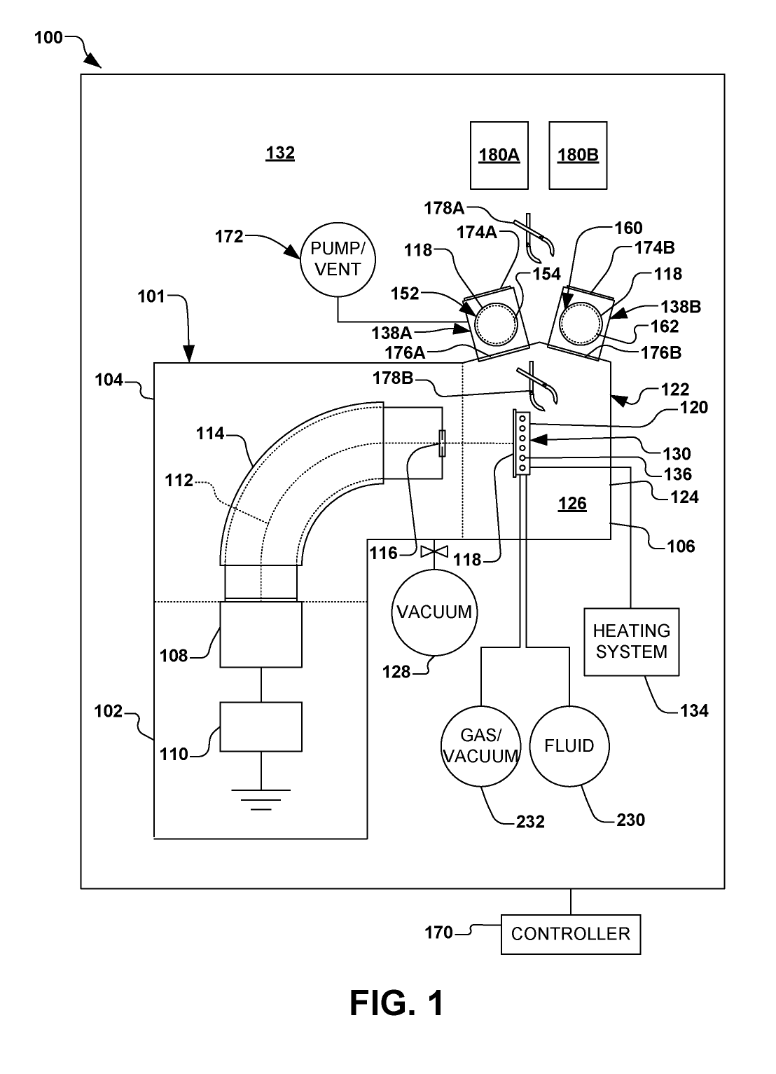

Thus, in accordance with one aspect of the present disclosure, FIG. 1 illustrates an exemplary ion implantation system 100. The ion implantation system 100 in the present example comprises an exemplary ion implantation apparatus 101, however various other types of vacuum-based semiconductor processing systems are also contemplated, such as plasma processing systems, or other semiconductor processing systems. The ion implantation apparatus 101, for example, comprises a terminal 102, a beamline assembly 104, and an end station 106.

Generally speaking, an ion source 108 in the terminal 102 is coupled to a power supply 110 to ionize a dopant gas into a plurality of ions and to form an ion beam 112. The ion beam 112 in the present example is directed through a mass analysis apparatus 114, and out an aperture 116 towards the end station 106. In the end station 106, the ion beam 112 bombards a workpiece 118 (e.g., a substrate such as a silicon wafer, a display panel, etc.), which is selectively clamped or mounted to a chuck 120 (e.g., an electrostatic chuck or ESC). Once embedded into the lattice of the workpiece 118, the implanted ions change the physical and/or chemical properties of the workpiece. Because of this, ion implantation is used in semiconductor device fabrication and in metal finishing, as well as various applications in materials science research.

The ion beam 112 of the present disclosure can take any form, such as a pencil or spot beam, a ribbon beam, a scanned beam, or any other form in which ions are directed toward end station 106, and all such forms are contemplated as falling within the scope of the disclosure.

According to one exemplary aspect, the end station 106 comprises a process chamber 122, such as a vacuum chamber 124, wherein a process environment 126 is associated with the process chamber. The process environment 126 generally exists within the process chamber 122, and in one example, comprises a vacuum produced by a vacuum source 128 (e.g., a vacuum pump) coupled to the process chamber and configured to substantially evacuate the process chamber.

In one example, the ion implantation apparatus 101 is configured to provide a high temperature ion implantation, wherein the workpiece 118 is heated to a process temperature (e.g., approximately 100-600° C.). Thus, in the present example, the chuck 120 comprises a heated chuck 130, wherein the heated chuck is configured to support and retain the workpiece 118 while further heating the workpiece 118 within the process chamber 122 prior to, during, and/or after the exposure of the workpiece to the ion beam 112.

The heated chuck 130, for example, comprises an electrostatic chuck (ESC) configured to heat the workpiece 118 to a processing temperature that is considerably greater than an ambient or atmospheric temperature of the surroundings or external environment 132 (e.g., also called an “atmospheric environment”). A heating system 134 may be further provided, wherein the heating system is configured to heat the heated chuck 130 and, in turn, the workpiece 118 residing thereon to the desired processing temperature. The heating system 134, for example, is configured to selectively heat the workpiece 118 via one or more heaters 136 disposed within the heated chuck 130.

For some high temperature implants, the workpiece 118 is allowed to “soak” on the heated chuck 130 within the vacuum of the process environment 126 until the desired temperature is reached. Alternatively, in order to increase cycle time through the ion implantation system 100 the workpiece may be pre-heated in one or more chambers 138A, 138B (e.g., one or more load lock chambers) operatively coupled to the process chamber 122 via a pre-heat apparatus 152.

Depending on the tool architecture, process, and desired throughput, the workpiece 118 may be preheated to the first temperature via the pre-heat apparatus 152, wherein the first temperature is equal to or lower than the process temperature, thus allowing for a final thermal equalization on the heated chuck 130 inside the vacuum chamber 124. Such a scenario allows the workpiece 118 to lose some heat during transfer to the process chamber 122, wherein final heating to the process temperature is performed on the heated chuck 130. Alternatively, the workpiece 118 may be preheated via the pre-heat apparatus 152 to a first temperature that is higher than the process temperature. Accordingly, the first temperature would be optimized so that cooling of the workpiece 118 during transfer to the process chamber 122 is just enough for the workpiece to be at the desired process temperature as it is clamped onto the heated chuck 130.

The pre-heat apparatus 152 associated with the one or more chambers (e.g., illustrated in chamber 138A in FIG. 1) can advantageously heat the workpiece 118 at the atmospheric pressure of the external environment 132 prior to bringing the workpiece to the vacuum of the process environment 126 of the process chamber 120. For example, heat transfer into the workpiece 118 in a high vacuum environment, such is within the process chamber 120, is largely dominated by radiation. Total hemispherical emissivity of crystalline silicon in temperatures between 300-500° C., for example, ranges between approximately 0.2 and 0.6, thus not lending itself well to fast thermal transients due to a low rate of irradiated heat absorption of the workpiece 118.

In order to accelerate the thermal ramp-up and enable an additional mechanism for heat transfer, the back side of the workpiece 118 is brought into conductive communication with the heated chuck 130. This conductive communication is achieved through a pressure controlled gas interface (also called “back side gas”) between the heated chuck 130 and the workpiece 118. Pressure of the back side gas, for example, is generally limited by the electrostatic force of the heated chuck 130, and can be generally kept in the range of 5-20 Torr. In one example, the back side gas interface thickness (e.g., the distance between the workpiece 118 and the heated chuck 130) is controlled on the order of microns (typically 5-20 μm), and as such, the molecular mean free path in this pressure regime becomes large enough for the interface thickness to push the system into the transitional and molecular gas regime.

Alternatively, the pre-heat apparatus 152 may heat the workpiece 118 at the vacuum pressure of the process environment 126. In yet another alternative, the pre-heat apparatus 152 may heat the workpiece 118 during the same timeframe that the one or more chambers 138A, 138B are being pumped down to transition from atmospheric pressure to vacuum pressure.

The pre-heat apparatus 152, for example, comprises a hot plate 154 positioned within the chamber 138A. The hot plate 154, for example, comprises a resistive heater, which could include a heating element embedded in the hot plate, a heat pump, or other heating mechanism for transmitting heat energy form the hot plate to the workpiece 118. Alternatively, the pre-heat apparatus 152 comprises a radiant heat source, such as one or more a halogen lamp, light emitting diode, and infrared thermal device.

In accordance with another aspect of the disclosure, chamber 1388 comprises a cooling apparatus 160 configured to cool the workpiece when the workpiece 118 is disposed within the chamber 1388 subsequent to being implanted with ions during ion implantation. The cooling apparatus 160, for example, may comprise a chilled workpiece support 162, wherein the chilled workpiece support is configured to actively cool the workpiece 118 residing thereon via thermal conduction. The chilled workpiece support 162, for example, comprises a cold plate having a one or more cooling channels passing therethrough, wherein a cooling fluid passing through the cooling channel substantially cools the workpiece 118 residing on a surface of the cold plate. The chilled workpiece support 162 may comprise other cooling mechanisms, such as Peltier coolers or other cooling mechanisms known to one of ordinary skill.

In accordance with another exemplary aspect, a controller 170 is further provided and configured to selectively activate the heating system 134, the pre-heat apparatus 152, and the cooling apparatus to selectively heat or cool the workpiece 118 respectively residing thereon. The controller 170, for example, may be configured to heat the workpiece 118 in chamber 138A via the pre-heat apparatus 152, to heat the workpiece to a predetermined temperature in the processing chamber 122 via the heated chuck 130 and heating system 134, to implant ions into the workpiece via the ion implantation apparatus 101, to cool the workpiece in chamber 1388 via the cooling apparatus 160, and to selectively transfer the workpiece between the atmospheric environment 132 and the vacuum environment 126 via control of a pump and vent 172, the respective atmospheric doors 174A, 1748 and vacuum doors 176A, 1768 of the respective chambers 138A, 138B, and workpiece transfer apparatus 178A, 178B.

In one example, the workpiece 118 may be further delivered to and from the process chamber 122 such that the workpiece is transferred between a selected front opening unified pod (FOUP) 180A, 180B and chambers 138A, 138B via workpiece transfer apparatus 178A, and further transferred between the chambers 138A, 138B and the heated chuck 130 via workpiece transfer apparatus 1788. The controller 170, for example, is further configured to selectively transfer the workpiece between the FOUPs 180A, 180B, chambers 138A, 138B, and heated chuck 130 via a control of the workpiece transfer apparatus 178A, 178B.

As stated previously, conventional ion implantation systems typically utilize various electrostatic chucks having differing configurations, whereby implants performed at different temperature ranges utilize respectively different electrostatic chucks having differing heat transfer capabilities. The system 100 of FIG. 1 of the present disclosure, however, is advantageously configured to perform both high temperature implants (e.g., in the range of 100-600° C.) and quasi-room temperature implants (e.g., in the range of 20-100° C.) while utilizing the same heated chuck 130. Such a configuration is advantageous over conventional systems in both simplicity, as well as productivity, as the system 100 of FIG. 1 may be utilized in various implantation schemes with minimal changes in configuration while mitigating various deficiencies commonly seen in conventional startup operations of conventional ion implantation systems.

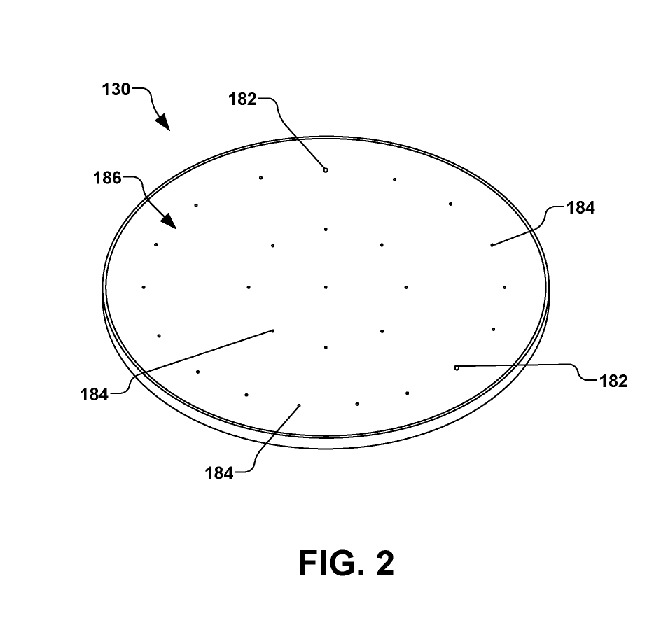

An exemplary heated chuck 130 is illustrated in FIG. 2, whereby the ESC, for example, serves two functions; namely, to clamp the workpiece 118 of FIG. 1, and to heat and/or cool the workpiece. One or more ground pins 182 shown in FIG. 2, for example, are provided for electrical grounding of the workpiece, and mesas 184 are provided on a top surface 186 of the ESC 130 in order to minimize contact with the workpiece 118 of FIG. 1 and to eliminate particle contamination.

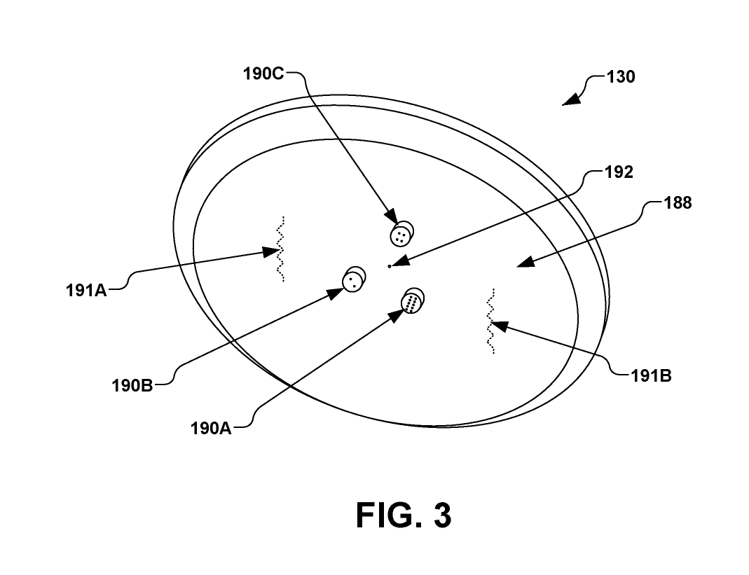

FIG. 3, for example, illustrates a backside 188 of the ESC 130, wherein a plurality of mechanical and electrical interfaces 190 are provided for the ESC. For example, a first interface 190A is provided for high voltage electrostatic electrodes (not shown) configured to electrostatically attract the workpiece to the ESC 130. A second interface 190B is provided for powering a dual-zone heater 191A, 191B embedded in the ESC 130. While not explicitly illustrated in the schematic shown in FIG. 3, the dual-zone heater 191A, 191B, for example, may be positioned within the ESC 130 to heat various regions of the ESC, such as one or more of a center region and peripheral region, and may be axially and/or radially positioned for a desired heating of the workpiece. A third interface 190C, for example, is further provided for temperature feedback through a resistance temperature detector (RTD) 192 embedded in the ESC 130 for temperature control.

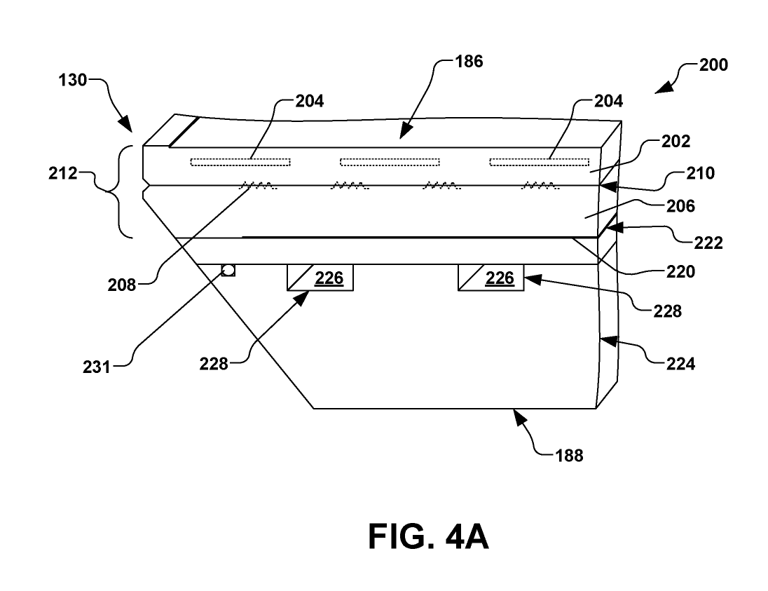

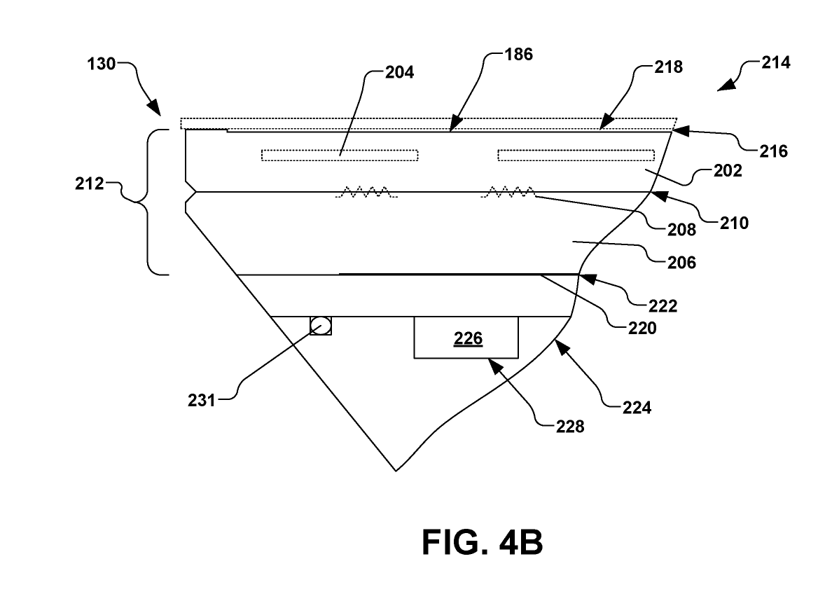

In accordance with another exemplary aspect of the disclosure, FIG. 4A illustrates a portion 200 of the ESC 130. For example, an upper carrier plate 202 is illustrated, whereby one or more high voltage electrodes 204 may be are implemented to clamp the workpiece (not shown) to the top surface 186 of the ESC 130. In one example, the upper carrier plate 202 is comprised of a ceramic material having the one or more high voltage electrodes 204 embedded therein, or otherwise associated therewith. The upper carrier plate 202, for example, is bonded to a heater carrier plate 206 having a heater 208 (e.g., one or more heating elements) associated therewith. For example, the heater carrier plate 206 may be comprised of a ceramic material, whereby the heater 208 is disposed at or proximate to an interface 210 between the upper carrier plate 202 and the heater carrier plate. The heater 208, for example, can be configured to actively heat or maintain the temperature of the workpiece 118 of FIG. 1 during an implantation process. The heater 208 of FIG. 4A, for example, can heat or otherwise maintain the workpiece temperature at 200-500 C or various other elevated temperature, as desired. The upper carrier plate 202 and heater carrier plate 206, for example, are collectively termed a carrier plate 212. Thus, the workpiece 118 of FIG. 1, for example, can be heated via the transfer of heat through the carrier plate 212 of FIG. 4A to the workpiece.

In one example, FIG. 4B illustrates a further blown up portion 214 of the portion 200 of the ESC 130 shown in FIG. 4B, wherein a backside gas (not shown) is provided in a backside gap 216 between the top surface 186 of the carrier plate 212 and the workpiece 118 residing thereon in order to heat or cool the workpiece. For example, a backside gas layer 218 (e.g., approximately 10 microns) is provided in the backside gap 216 to conduct heat from the workpiece 118 to the chuck 130 in a cooling mode, or the heater 208 can conduct heat from the chuck to the workpiece for providing or maintaining a higher temperature.

In accordance with another exemplary aspect, the present disclosure further provides a heat transfer media 220 positioned in a gap 222 (e.g., approximately 10 microns) between the carrier plate 212 and a base plate 224, whereby the same ESC 130 can be utilized for both room temperature (RT) operation and heated implants at elevated temperatures. For example, in a first embodiment, the heat transfer media 220 (e.g., a ductile material that has a low thermal resistance) is provided between the carrier plate 212 and the base plate 224 so that heat from the workpiece 118 can be transferred through the upper carrier plate 202 and the heater carrier plate 206 (e.g., both being ceramic plates) to a cooling fluid 226 in one or more cooling channels 228 in the base plate 224 (e.g., comprised of aluminum). The heat transfer media 220, for example, may comprise a flexible or ductile material that has a high heat transfer ability. For example, the heat transfer media 220 may comprise a silicone base with carbon or other adequate conductor of heat disposed therein. The heat transfer media 220 may alternatively comprise other materials such as a flexible polymer or a gel, thermal paste, or other material that provides good surface contact between the carrier plate 212 and the base plate 224.

In a second embodiment, a thin layer of gas (not shown) is provided as the heat transfer media 220 in the gap 222 between the carrier plate 212 and the base plate 224. For example, in a room temperature operation, a heat transfer gas can be provided as the heat transfer media 220 at a predetermined gas pressure (e.g., approximately 5 Torr) within the gap 222 in order to conduct heat from the carrier plate 212 through to the base plate 224, and further to the cooling fluid 226 (e.g., water) provided in the one or more cooling channels 228 via a cooling fluid system 230 shown in FIG. 1. Alternatively, a vacuum may be provided in the gap 222 of FIG. 4B in order to generally thermally isolate the carrier plate 212 from the base plate 224, thus generally preventing heat that may exist during a heated operation from transferring to the cooling channels 228 in the base plate.

In either the first or second embodiment, the cooling fluid 226 within the one or more cooling channels 228 could be advantageously evacuated, such that deleterious issues associated with boiling of the cooling fluid (e.g., water) would be substantially eliminated during a heated operation of the ESC 130. For example, in some cases, the cooling fluid 226 can be purged from the ESC 130, whereby no cooling is provided therefrom. Alternatively, the cooling fluid 226 may be flowed through the ESC 130 at a lower rate, or external cooling of the cooling fluid may be altered, such that a lesser amount of cooling is provided to the base plate 224 to mitigate potential thermal damage to an o-ring 231 or other feature(s) associated with the ESC 130

The one or more cooling channels 228, in one example, are filled with water as the cooling fluid 226 such that the water is flowed therethrough in order to conduct heat from (e.g., take heat away from) the workpiece 118 as the heat is conducted though the backside gas layer 218, carrier plate 212, and heat transfer media 220 to the base plate 224, such as would be desirable for a room temperature operation of the ESC 130. In such an operation, the water would flow through the one or more cooling channels 226 in the ESC 130 to remove heat from the ESC and transfer the heat to an external heat exchanger.

Accordingly, in the present example, the structure of the ESC 130 can remain generally unchanged, except that a gas is either provided as the heat transfer media 220 in the gap 222 or evacuated from the gap between the carrier plate 212 and base plate 224, and/or water in the one or more cooling channels 226 of the base plate 224 is either flowed through, or evacuated from, the one or more cooling channels, in order to provide various modes of operation of the ESC without mechanically modifying the ESC.

For example, in a first mode of operation (e.g., a room temperature mode of operation), a gas is provided by a gas delivery system 232 of FIG. 1 to the gap 222 between the carrier plate 212 and base plate 224 of FIG. 4B, whereby the gas can be delivered at approximately 5 Torr for providing a good thermal conduction path to transfer heat from the workpiece 118 through to the cooling fluid 226 in the one or more cooling channels 228. Such a first mode of operation, for example, can be desirable in a room temperature ion implantation. The first mode of operation, for example, may be likewise practiced in the first embodiment, where the heat transfer media 222 conducts heat between the carrier plate 212 and base plate 224 to the cooling fluid 226 in the one or more cooling channels 228.

Alternatively, in a second mode of operation (e.g., a heated mode of operation), the gas delivery system 232 of FIG. 1 can be configured to selectively evacuate the gap 222 to define a vacuum between the carrier plate 212 and the base plate 224 in order to minimize heat transfer from the one or more heaters 208 to the cooling fluid 226 in the one or more cooling channels 228. Such a second mode of operation, for example, can be desirable for a heated ion implantation operation, where the workpiece 118 is heated to higher temperatures (e.g., greater than 200 C). Again, the water or other cooling fluid 226 may be evacuated from the cooling channel 228 by the cooling fluid system 230 of FIG. 1 during the second mode of operation (e.g., heated operation) in either of the first embodiment or second embodiment, discussed above.

It is noted that in a heated operation utilizing the above-mentioned flexible material as the heat transfer media 222 of FIG. 4B and water as the cooling fluid 228, it may be preferable to evacuate the water from the one or more cooling channels 228 via the cooling fluid system 230 of FIG. 1 in order to minimize the possibility of boiling the water.

The present disclosure thus provides a system that is capable of actively cooling and/or actively heating a workpiece at either room temperature (e.g., active cooling to remove heat from the workpiece due to the heat involved in the implantation process), or heating the workpiece to an elevated temperature (e.g., active addition of heat to the workpiece for a heated implantation process). The ion implantation system 101 of FIG. 1, for example, may advantageously incorporate the ESC 130 and associated systems, as discussed above. For example, the preheat apparatus 152 may be utilized to increase the temperature of the workpiece 118 to a desired temperature, whereby the ESC 130 maintains or sets the implant temperature, and where cooling of the workpiece is further provided after implantation via the cooling apparatus 160.

Accordingly, the system of the present disclosure is operable to perform any or all of the above operations in one system, where the physical structure of the system is unchanged, while operating conditions or fluids passed through the system are simply changed or modified. As such, the present disclosure provides a plurality of modes of operation utilizing the same physical heated chuck 130.

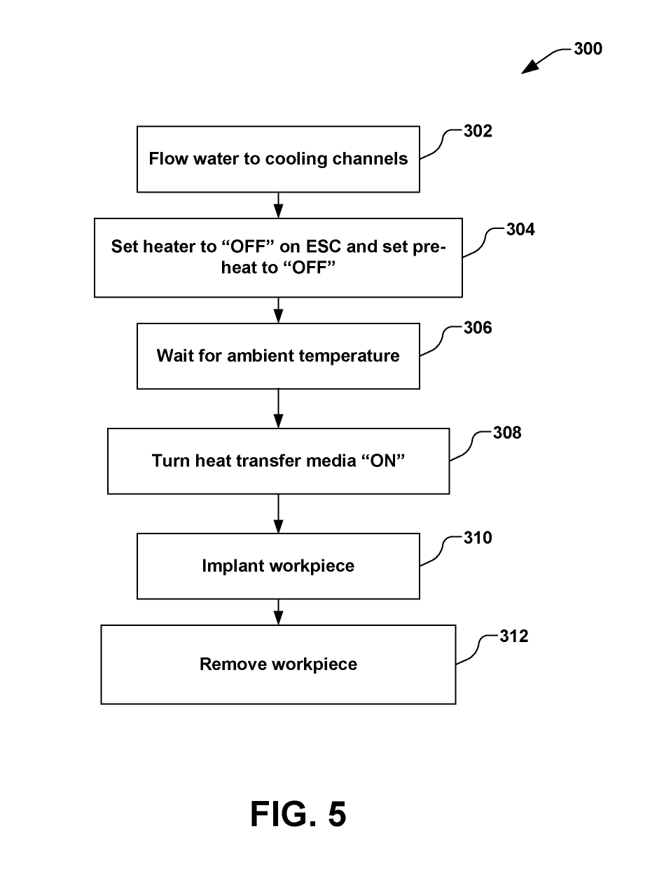

In another aspect of the disclosure, FIG. 5 illustrates a method 300 for processing workpieces in the first mode of operation. It should be noted that while exemplary methods are illustrated and described herein as a series of acts or events, it will be appreciated that the present disclosure is not limited by the illustrated ordering of such acts or events, as some steps may occur in different orders and/or concurrently with other steps apart from that shown and described herein, in accordance with the disclosure. In addition, not all illustrated steps may be required to implement a methodology in accordance with the present disclosure. Moreover, it will be appreciated that the methods may be implemented in association with the systems illustrated and described herein as well as in association with other systems not illustrated.

The method 300 shown in FIG. 5 illustrates an example of the system operated in the first mode of operation, or active cooling for room temperature Implantation of ions into the workpiece. Initially, as illustrated in FIG. 5, a water pumping and/or valving system flows cooling water into the cooling lines of a scan robot and the cooling channels in the ESC in act 302. The one or more heaters in the ESC are set to “OFF”, and the pre-heat station is set to “OFF”. Once ambient temperatures are achieved in act 306 (e.g., in approximately 60 minutes), the ion implantation system is ready for production. The heat transfer media is turned “ON” in act 308, thus providing the heat transfer gas between to the gap between the carrier plate and base plate. Workpiece handling and implantation of ions into the workpiece is performed in act 310, and the workpiece is removed from the ESC in act 312.

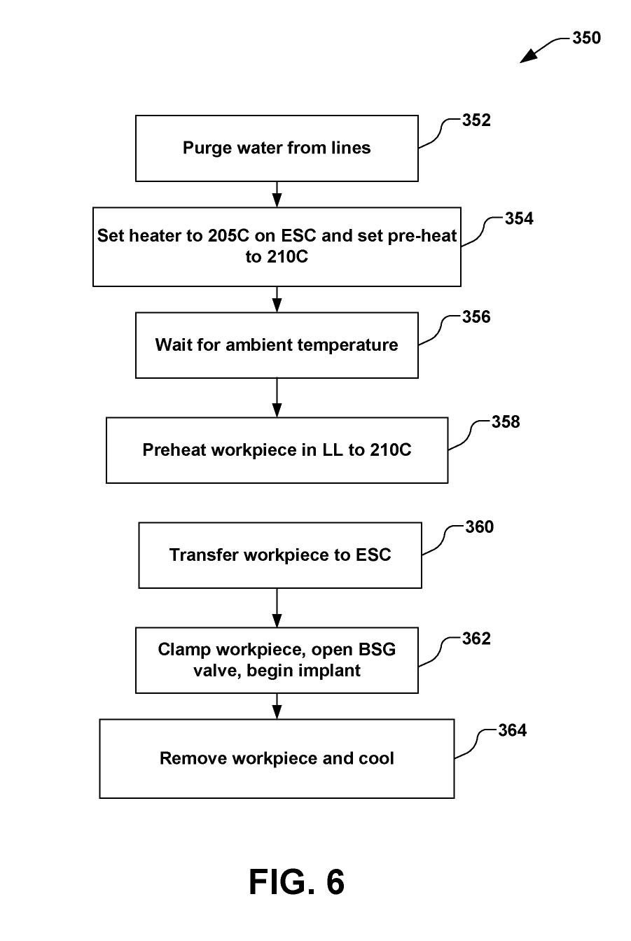

The method 350 shown in FIG. 6 illustrates an example of the system operated in the second mode of operation with active heating (e.g., for a heated implant at 200 C). A water pumping and/or valving system, for example, optionally purges cooling water from the ESC and lines in the scan robot in act 352 (e.g., no water flows through the ESC). For example, in some cases, the cooling water can be purged from the ESC, whereby no cooling is provided therefrom. Alternatively, the cooling water may be flowed through the ESC at a lower rate, or external cooling of the cooling water may be altered, such that a minor amount of cooling is provided to the base plate (e.g., to thermally protect o-rings or other features of the ESC). The ESC heater is set to approximately 205 C, and the pre-heat station is set to approximately 210 C in act 354. Once desired temperatures are achieved in act 356 (e.g., in approximately 60 minutes), the system is ready for production. The workpiece is pre-heated in the load lock to approximately 210 C in act 358. The workpiece is then transferred onto the ESC in act 360. The workpiece is clamped, the backside gas (BSG) valve opens (e.g., providing approximately 5 Torr of backside gas pressure-BSGP), and the ion implantation starts in act 362. After the workpiece is implanted with ions, the workpiece is transferred from the ESC to the post-cool station and cooled to less than approximately 80 C in the load lock chamber in act 364.

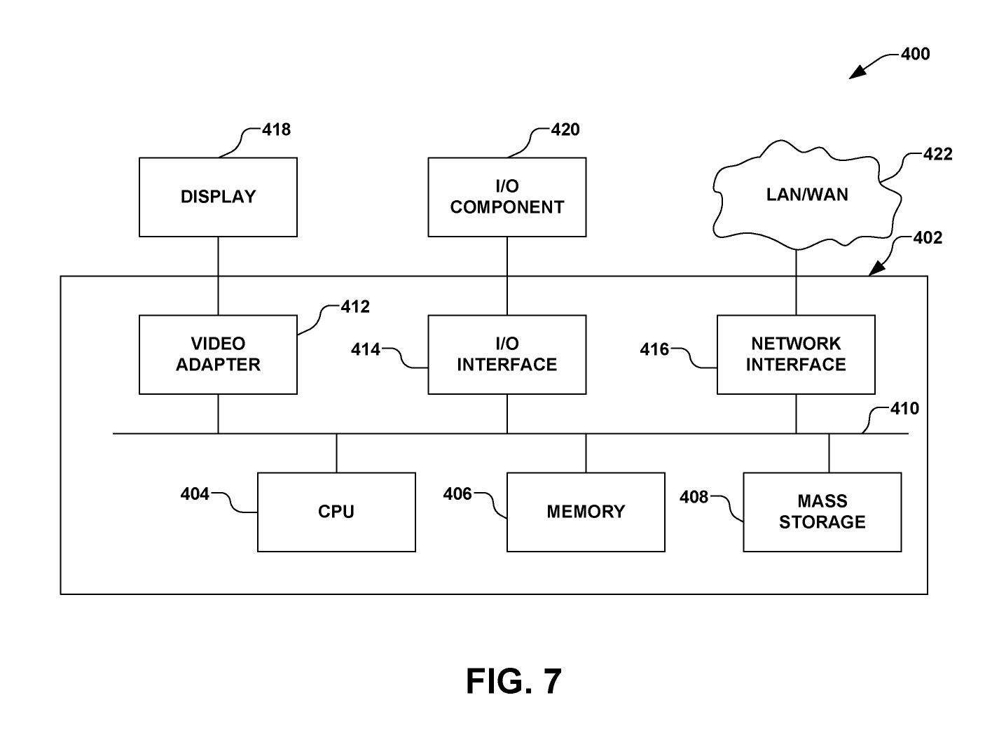

In accordance with another aspect, the aforementioned methodology may be implemented using computer program code in one or more of a controller, general purpose computer, or processor based system. As illustrated in FIG. 7, a block diagram is provided of a processor based system 400 in accordance with another embodiment. The processor based system 400 is a general purpose computer platform and may be used to implement processes discussed herein. The processor based system 400 may include a processing unit 402, such as a desktop computer, a workstation, a laptop computer, or a dedicated unit customized for a particular application. The processor based system 400 may be equipped with a display 418 and one or more input/output devices 420, such as a mouse, a keyboard, or printer. The processing unit 402 may include a central processing unit (CPU) 404, memory 406, a mass storage device 408, a video adapter 412, and an I/O interface 414 connected to a bus 410.

The bus 410 may be one or more of any type of several bus architectures including a memory bus or memory controller, a peripheral bus, or video bus. The CPU 304 may include any type of electronic data processor, and the memory 306 may include any type of system memory, such as static random access memory (SRAM), dynamic random access memory (DRAM), or read-only memory (ROM).

The mass storage device 408 may include any type of storage device configured to store data, programs, and other information and to make the data, programs, and other information accessible via the bus 410. The mass storage device 308 may include, for example, one or more of a hard disk drive, a magnetic disk drive, or an optical disk drive.

The video adapter 412 and the I/O interface 414 provide interfaces to couple external input and output devices to the processing unit 402. Examples of input and output devices include the display 418 coupled to the video adapter 412 and the I/O device 420, such as a mouse, keyboard, printer, and the like, coupled to the I/O interface 414. Other devices may be coupled to the processing unit 402, and additional or fewer interface cards may be utilized. For example, a serial interface card (not shown) may be used to provide a serial interface for a printer. The processing unit 402 also may include a network interface 416 that may be a wired link to a local area network (LAN) or a wide area network (WAN) 422 and/or a wireless link.

It should be noted that the processor based system 400 may include other components. For example, the processor based system 400 may include power supplies, cables, a motherboard, removable storage media, cases, and the like. These other components, although not shown, are considered part of the processor based system 400.

Embodiments of the present disclosure may be implemented on the processor based system 400, such as by program code executed by the CPU 404. Various methods according to the above-described embodiments may be implemented by program code. Accordingly, explicit discussion herein is omitted.

Further, it should be noted that various modules and devices in FIGS. 1-6 may be implemented on and controlled by one or more processor based systems 400 of FIG. 7. Communication between the different modules and devices may vary depending upon how the modules are implemented. If the modules are implemented on one processor based system 400, data may be saved in memory 406 or mass storage 408 between the execution of program code for different steps by the CPU 404. The data may then be provided by the CPU 404 accessing the memory 406 or mass storage 408 via bus 410 during the execution of a respective step. If modules are implemented on different processor based systems 400 or if data is to be provided from another storage system, such as a separate database, data can be provided between the systems 400 through I/O interface 414 or network interface 416. Similarly, data provided by the devices or stages may be input into one or more processor based system 300 by the I/O interface 414 or network interface 416. A person having ordinary skill in the art will readily understand other variations and modifications in implementing systems and methods that are contemplated within the scope of varying embodiments.

Although the disclosure has been shown and described with respect to a certain preferred embodiment or embodiments, it is obvious that equivalent alterations and modifications will occur to others skilled in the art upon the reading and understanding of this specification and the annexed drawings. In particular regard to the various functions performed by the above described components (assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the disclosure. In addition, while a particular feature of the disclosure may have been disclosed with respect to only one of several embodiments, such feature may be combined with one or more other features of the other embodiments as may be desired and advantageous for any given or particular application.

What is claimed is:

1. A workpiece processing system, comprising:
an ion implantation system configured to implant ions into a workpiece;
a heated chuck positioned within a process chamber, wherein the heated chuck is configured to selectively clamp the workpiece thereto, and wherein the heated chuck comprises:
a carrier plate having a clamping surface for clamping the workpiece thereto, the carrier plate having one or more heaters embedded therein, wherein the one or more heaters are configured to selectively heat the clamping surface;
a base plate operably coupled to the carrier plate, wherein a gap is provided between the base plate and carrier plate, and wherein one or more cooling channels are defined in the base plate; and
a heat transfer media disposed within the gap;
a source of a cooling fluid selectively operably coupled to the cooling channel; and
a controller configured to selectively operate the ion implantation system in one of a first mode and second mode, wherein in the first mode, the controller is configured to not activate the one or more heaters and to flow the cooling fluid through the cooling channel, and wherein heat is transferred through the heat transfer media between the carrier plate and base plate, therein transferring heat to the cooling fluid, and wherein in the second mode, the controller is configured to activate the one or more heaters to a predetermined temperature.

2. The workpiece processing system of claim 1, further comprising a gas source and a vacuum source, wherein the heat transfer media comprises a gas, wherein the controller is further configured to selectively supply the gas from the gas source to the gap at a predetermined pressure in the first mode via a control of the gas source, therein selectively thermally coupling the carrier plate to the base plate, and wherein the controller is further configured to selectively evacuate the gap via a control of the vacuum source in the second mode, therein selectively thermally isolating the carrier plate from the base plate.

3. The workpiece processing system of claim 2, further comprising purging the cooling fluid from the cooling channel in the second mode.

4. The workpiece processing system of claim 1, wherein the gap is approximately 10 microns.

5. The workpiece processing system of claim 1, wherein the heat transfer media comprises one or more of a gel, a flexible material, and a paste configured to transfer heat between the carrier plate and base plate.

6. The workpiece processing system of claim 1, wherein the heated chuck is configured to heat the workpiece to a predetermined processing temperature.

7. The workpiece processing system of claim 6, wherein the predetermined processing temperature ranges from approximately 100 C to approximately 200 C.

8. The workpiece processing system of claim 1, further comprising one or more of a pre-heat station and a post-cooling station.

9. A method for implanting ions into a workpiece in a plurality of modes, the method comprising:
selectively operating a heated chuck of an ion implantation system in one of a first mode and second mode,
wherein in the first mode, one or more heaters in the heated chuck are deactivated and a cooling fluid is flowed through a cooling channel in the heated chuck, wherein heat is transferred through a heat transfer media disposed in a gap between a carrier plate and a base plate of the heated chuck, therein transferring heat to the cooling fluid, and
wherein in the second mode, the one or more heaters are activated to a predetermined temperature.

10. The method of claim 9, wherein the heat transfer media comprises a gas, wherein in the first mode, the gas is supplied to the gap at a predetermined pressure, therein thermally coupling the carrier plate to the base plate, and wherein in the second mode, the gap is evacuated, therein generally thermally isolating the carrier plate from the base plate.

11. The method of claim 10, further comprising purging the cooling fluid from the cooling channel in the second mode.

12. The method of claim 9, wherein the gap is approximately 10 microns.

13. The method of claim 9, wherein the heat transfer media comprises one or more of a gel, flexible material, and paste configured to transfer heat between the carrier plate and base plate.

14. The method of claim 9, wherein the heated chuck heats the workpiece to a predetermined processing temperature.

15. The method of claim 9, wherein the predetermined temperature is approximately room temperature in the first mode and ranges from approximately 100 C to approximately 200 C in the second mode.

16. The method of claim 9, further comprising performing an ion implantation into the workpiece.

17. The method of claim 16, further comprising one or more of pre-heating the workpiece before the implantation and post-cooling the workpiece after the implantation.

18. The method of claim 9, further comprising electrostatically clamping the workpiece to a clamping surface of the heated chuck.

19. A heated chuck for an ion implantation system, the heated chuck comprising:
a carrier plate;
a base plate having a cooling channel defined therein, wherein the base plate is operably coupled to the carrier plate, wherein a gap is defined between the carrier plate and the base plate, and wherein a heat transfer media is selectively provided in the gap; and
one or more heaters, wherein the heated chuck is configured to be selectively operable in a first mode and second mode, wherein in the first mode, the one or more heaters are not active and a cooling fluid is flowed through the cooling channel in the base plate, wherein heat is transferred through the heat transfer media between the carrier plate and base plate, and wherein in the second mode, the one or more heaters are activated to a predetermined temperature.

20. The ion implantation system of claim 19, further comprising:
a source of a cooling fluid selectively operably coupled to the cooling channel; and
a controller configured to selectively control an operation of the heated chuck in the first mode and second mode via a control of the one or more heaters, the source of the cooling fluid, and the heat transfer media.
